(19) United States
(12) Patent Application Publication
(10) Pub. No.: US 2002/0064035 A1
(43) Pub. Date: May 30, 2002

(54) Subrack and composite subrack

(76) Inventors: Eduard Mair, Muenchen (DE); Peter Sedlmeier, Muenchen (DE)

Correspondence Address: SCHIFF HARDIN & WAITE, 6600 SEARS TOWER, 233 S WACKER DR, CHICAGO, IL, 60606-6473, US

(21) Appl. No.: 09/884,620

(22) Filed: Jun. 19, 2001

(30) Foreign Application Priority Data
Jun. 20, 2000 (DE) 100 30 233.5

(51) Int. Cl. H05K 7/14; H05K 7/18

(52) U.S. Cl. 361/800

(57) ABSTRACT

The invention relates to a subrack (9) for a composite subrack (14) for receiving modules. Furthermore, the tow subracks (9) arranged one vertically above the other. The invention is distinguished by the fact that the composite subrack (14) contains at least two subracks (9), the upper side (20) and underside (24) of which are respectively provided with at least one clearance (13) over a large area, and two shielding plates (7) are provided, shielding the upper side (20) of the upper subrack (9) and the underside (24) of the lower subrack (9).

### BACKGROUND OF THE INVENTION

1. Field of the Invention

The invention relates to a subrack for a composite subrack with two side walls, an upper side, an underside, a front side and a rear wall, for receiving modules. Furthermore, the invention relates to a composite subrack with at least two subracks arranged one vertically above the other, the subracks having two side walls, an upper side, an underside, a front side and a rear wall, for receiving modules.

2. Description of the Related Art

A subrack is a casing which can receive a number of modules. In the case of a shielded subrack, the rear wall (backplane) of the subrack electrically interconnects the inserted modules and has integrated shielding layers, i.e., full-area electrically conducting planes, which are pressed as an integral part of the printed-circuit board and are electrically bonded to the casing at all the edges of the board. The wiring plate, like the metallic casing of the subrack, should be impermeable to inward or outward emission of high-frequency electrical waves. A removable front covering closes off the subrack on the operator side and a bottom plate and a top plate are perforated over a large area to achieve the highest possible throughput of air for dissipating the power loss of the modules, i.e., to achieve good cooling of the subrack.

In electrical terms, the subrack should form a Faraday's cage around the modules, since the aim is to avoid or shield the outward and inward emission of interference from and to these modules.

However, here the problem arises that the shielding effectiveness and cooling capability of the subrack act in a conflicting manner. To improve the cooling capability, the flow resistance to the air flowing through the subrack would have to be reduced. This can be achieved by increasing the openness of the perforation of the bottom and top plates. However, this is at the expense of a deterioration in the shielding effectiveness of the subrack.

If dissipation of the power loss by free convection is no longer possible, fans are fitted. However, this has the disadvantage that the fan units take up considerable space.

A composite subrack is a rack in which usually a number of subracks are fitted one vertically above the other. Each individual subrack draws in its cooling air from the underside and discharges it again in the upward direction. Consequently, each time it flows over into the next shielded subrack, the air passes two resistance zones, that is in each case the top plate and the bottom plate. If a composite subrack is fully occupied with eight two-tier subracks, the flow resistance is accumulated altogether sixteen-fold and an effective cooling capability is problematical.

### SUMMARY OF THE INVENTION

It is therefore an object of the invention to develop a subrack for a composite subrack and to develop a composite subrack which provide an improvement in the cooling capability when the subracks are fitted into the composite subrack, without the electrical shielding of the modules within the subrack being impaired.

The object of developing a subrack and a composite subrack is achieved by a subrack for a composite subrack comprising: two side walls; an upper side; an underside; a front side; and a rear wall, for receiving modules, wherein both the upper side and the underside of the subrack are respectively provided with at least one clearance over a large area.

The object of the invention is also achieved by a composite subrack comprising: at least two subracks arranged one vertically above the other, the subracks constructed as described in the previous paragraph, and two shielding plates each shielding at least one large-area clearance, shielding at least one large-area clearance of the upper side of the upper subrack and shielding at least one large-area clearance of the underside of the lower subrack.

The subrack and composite subrack are explained in more detail below.

The inventors have realized that the top and bottom plates of the subracks located in the interior of the composite subrack are not required for electrical shielding of the modules if the composite subrack itself forms a Faraday's cage. Consequently, if these top and bottom plates are provided with clearances over a large area, they are then no longer relevant with regard to flowing of the air, or no longer hinder the free convection of the air, although the modules are still electrically shielded within the subrack.

In accordance with this realization, the inventors provide a further development of a subrack for a composite subrack with two side walls, an upper side, an underside, a front side and a rear wall, for receiving modules, to the extent that both the upper side and the underside of the subrack are respectively provided with at least one clearance over a large area. Advantageously, between three and nine large-area clearances are provided so that struts remain on the upper side and underside of the subrack that have a stabilizing effect.

This subrack according to the invention represents a basic element which no longer has EMC-effective (EMC=electromagnetic compatibility) restrictions on its upper side and on its underside.

In an advantageous configuration of the subrack according to the invention, the surface area of the at least one large-area clearance accounts for between 50% and 90%, preferably between 70% and 90%, of the entire surface area of the upper side or the underside of the subrack.

A further configuration of the subrack provides that webs, preferably edge webs, are provided on the upper side and on the underside of the subrack. The webs preferably have, at least partly, a perforation. This perforation can be used for example for fastening other parts to the subrack.

A particularly advantageous embodiment of the subrack according to the invention provides electrical bonding elements on the edge of each side wall of the subrack situated toward the upper side. These electrical bonding elements are designed in such a way that they can be snap-fitted onto the edges of the side wall.

Furthermore, the electrical bonding elements, which preferably comprise two comb-shaped springs, may be provided on the upper side, situated toward the front side of the subrack. These entities are preferably arranged in a U-shaped manner. The invention provides a strut which interconnects the side walls for fastening the springs on the subrack. The electrical bonding elements are fastened to this strut in an advantageous way, e.g., they are screwed on.

In another further development, further electrical bonding elements are provided on the upper side, situated toward the rear wall of the subrack. In a preferred embodiment, these entities have a triangular shape and can be fastened with the aid of a rail on the upper side of the subrack, the springs advantageously being merely pushed over the rail.

In a further development of the subrack according to the invention, a front covering with electrical bonding elements which bond the subrack is provided. The front covering closes off the subrack toward the operator side.

The electrical bonding elements are preferably of a flexible and electrically conducting design. For instance, the electrical bonding elements may take the form of a contact spring, preferably a metallic contact spring. Hereafter, too, bonding is understood as meaning electrical bonding.

A further advantageous configuration provides at least one, preferably two, shielding plates, which shield the at least one large-area clearance of the upper side and/or the underside of the subrack.

In an advantageous further development of the subrack according to the invention, the shielding plate has, at least partly, a perforation. As a result, simple mounting of the shielding plate on the upper side and the underside of the subrack is possible, for example via screws or rivets.

In addition, the shielding plate may have a multiplicity of regularly distributed holes (perforation), the entire open surface area of the holes (openness) lying in the range between 50% and 80%, preferably between 65% and 75%, of the entire surface area of the shielding plate. This open surface area of the holes is preferably as large as possible, to achieve an optimum cooling capability, the size of the holes being dependent on the frequency to be shielded. The higher the frequency, the smaller the size of the holes should be. An advantageous configuration of the shielding plate provides that, for shielding a frequency of 0 to 1 GHz, the holes of the shielding plate have a diameter of preferably around 4 mm.

To ensure the stability of the shielding plate, the distribution of the holes is dependent on the strength of the material used. In the case of high-strength materials, the open surface area of the holes may lie at the upper limit, that is to say at around 80%.

In addition, an optimum cooling capability depends on the extent of the perforated area. This extent preferably lies in the range between 80% and 95% of the entire surface area of the shielding plate.

Consequently, the configuration according to the invention of the shielding plate ensures not only a high air throughput through the subrack but also high electrical shielding. In particular, the frequencies of the mobile radio range are reliably shielded.

Furthermore, the shielding plate may have, at least at the edge facing toward the front side of the subrack, at least one, preferably more, bonding entity for the bonding of the shielding plate, at least to the subrack. The bonding entity is preferably in the form of a contact spring, which may be of a comb-like design.

With these configurations according to the invention, the subrack is then an EMC-effective casing, which represents a Faraday's cage for the modules within the subrack.

The inventors also provides further development of a composite subrack with at least two subracks arranged one vertically above the other, the subracks having two side walls, an upper side, an underside, a front side and a rear wall, for receiving modules, to the extent that at least two subracks, preferably all the subracks, are designed according to the invention, as described above, and, furthermore, two shielding plates are provided, shielding the upper side of the upper subrack and/or the underside of the lower subrack. The shielding plates are also designed according to the invention, as described above. The shielding plates are consequently attached according to the invention to the bottom of the lowermost subrack and the top of the uppermost subrack.

The intermediate planes required for the subrack guides (that is the upper sides and undersides of the subracks located in the interior of the composite subrack) are provided with clearances over a large area and are consequently no longer relevant with regard to flowing of the air, or no longer hinder the free convection of the air.

The construction of the composite subrack may consequently vary from two subracks to the full complement, that is, e.g., eight subracks. The invention also envisages retrofitting or exchanging of individual subracks in the composite subrack.

According to the invention, the height division of designs introduced is not exceeded, to provide downward compatibility. As a result, an exchange of subracks, old for new, is made possible, even if they are in the middle of the composite subrack. The height of the slot becoming free consequently advantageously corresponds to the height of the new subrack. The introduced designs of the existing subracks are consequently compatible with the subracks according to the invention.

Furthermore, the electrical bonding extends right over all the subracks, up to the ends of the composite subrack.

This consequently achieves the effect that the subracks according to the invention in the composite subrack can be coupled vertically to one another in such a way that they are electrically connected to form a single shielding casing. With the exception of the lowermost bottom plate and the uppermost top plate (which in each case may represent a shielding plate designed according to the invention), no further plates for shielding are required in the horizontal planes. The overall flow resistance is consequently reduced considerably and a high throughput of air is made possible.

A shielding plate with a known hole geometry, for example a 60° V-grid 5×4^{φ}, has a flow resistance of around 3. In comparison with modules with a target value below 8, it is evident that the flow resistance of two perforated plates is of the same order of magnitude and consequently significantly influences free convection. The composite subrack according to the invention acts in a way similar to a chimney and offers a distinctly increased cooling capacity.

An advantageous further development of the composite subrack according to the invention provides a connection frame between two subracks. The subracks according to the invention can then be retrofitted to existing known subracks to form composite subracks, so that a distinct improvement in the cooling capability is achieved by exchanging at least two or more subracks.

In a configuration of the composite subrack according to the invention, the connection frame has, at least partly, a perforation for fastening to one of the two adjacent subracks. The connection frame may be securely mounted, for example screwed, to the webs of the upper side or the underside of a first subrack.

Furthermore, according to the invention, the connection frame may have a multiplicity of bonding elements, which are arranged on the upper side or on the underside of the connection frame. The bonding elements in this case bond to the webs of the second subrack in such a way as not to produce a rigid mechanical connection.

This configuration achieves the effect of not forming a sizeable rigid arrangement, in order, on the one hand, to allow compensation for tolerances and on the other hand to permit the required freedom of movement in the event of mechanical stresses, that are caused, for example, by earthquakes.

The bonding element may in this case once again be of a flexible and electrically conducting design, preferably as metallic contact springs.

Another development of the composite subrack according to the invention provides that the connection frame has at least one bonding element at the edge lying toward the front side of the subrack, the bonding element bonding at least the underside of the upper subrack and the upper side of the lower subrack. With a closed front covering, this bonding element is additionally pressed into place and bonded by the bonding element of the front covering, so that the connection frame is also electrically connected to the front covering.

In an advantageous way, the bonding element is bent in a U-shaped form. Furthermore, there is also electrical conductivity and flexibility.

In a further advantageous embodiment of the composite subrack according to the invention, the connection frame comprises, at least partly, a C profile, the opening of the C profile facing inward. A fastening element can advantageously be lowered into the C profile.

### DESCRIPTION OF THE DRAWINGS

Further features of the invention emerge from the following description of various exemplary embodiments with reference to the drawings, in which:

FIG. 1 is a perspective view showing a first variant of the composite subrack according to the invention, comprising two subracks;

FIG. 2 is a cross sectional view showing a section through part of the composite subrack according to the invention;

FIG. 3 is an exploded perspective view showing a detail with the connection frame and contact spring;

FIG. 4 is a perspective view showing a preferred exemplary embodiment of the composite subrack according to the invention, comprising two subracks;

FIG. 5 is a perspective view showing a detail of the preferred exemplary embodiment of the bonding of two subracks;

FIG. 6 is a cross sectional view through part of the composite subrack according to the invention showing the bonding of the front covers;

FIG. 7 is a cross sectional view of the composite subrack according to the invention showing the bonding of an upper side and an underside;

FIG. 8 is a cross sectional view of a part of the composite subrack according to the invention showing the bonding of the front covers to the shielding plate; and

FIG. 9 is a cross sectional view of a part of the composite subrack according to the invention showing the fastening of the shielding plate to the underside.

### DETAILED DESCRIPTION OF THE INVENTION

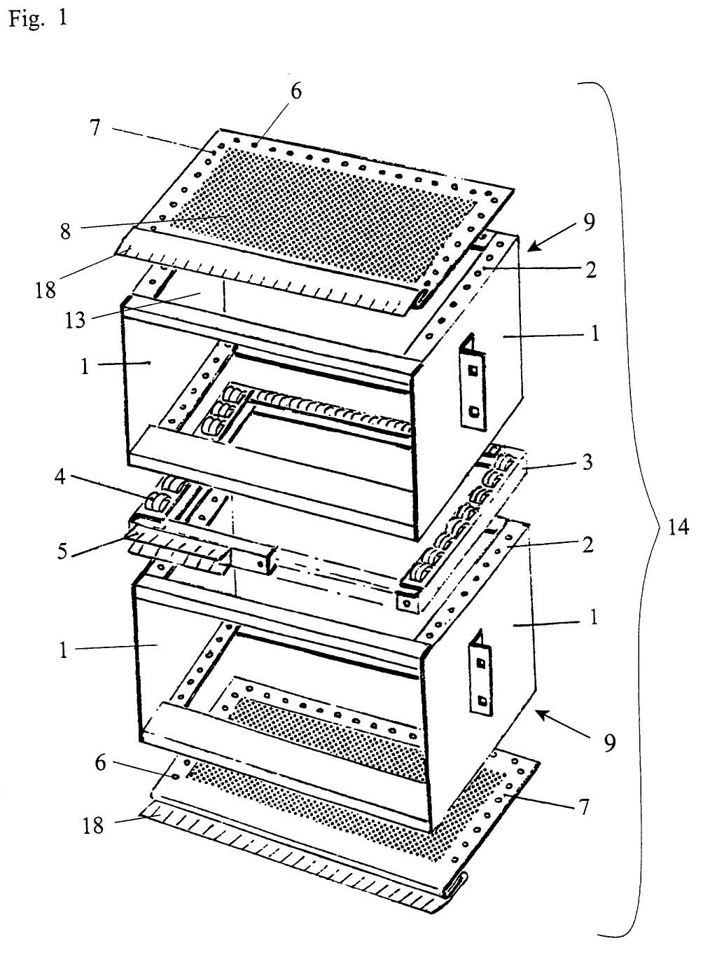

FIG. 1 shows a composite subrack according to the invention, which, for better overall clarity, contains only two subracks. The composite subrack can be extended in the upward and downward directions to accommodate additional subracks.

In the present exemplary embodiment, the composite subrack 14 comprises two subracks 9 according to the invention, a connection frame 3 between these subracks 9 and two shielding plates 7 at the upper end and lower end of the composite subrack 14.

The two vertical side walls 1 of each subrack 9 are bent inward at the upper edge and lower edge of the side wall 1 by 90 degrees and form U-shaped surface areas, which appear on the upper side and on the underside of the subrack 9 as edge webs 2. These webs 2 are perforated at short intervals, that is for example every 25 mm. These holes are required for screwing on the exact-fit connection frame 3 and the shielding plates 7.

The connection frame 3 fits between two neighboring subracks 9, although it is securely connected only to one of the two subracks 9, here the lower of the two. The opposite side of the connection frame 3, that is the side which is not securely connected to the subrack 9, is fitted with a multiplicity of contact springs 4 and bonds with the webs 2 (with the flange area) of the upper subrack 9. It is important not to form any further rigid connection here, for example to compensate for tolerances or to permit the required freedom of movement in the event of mechanical stresses.

A bonding of a front covering (not represented here) of each subrack 9 is established by the contact springs 5 bent in a U-shaped form, which are arranged as a component part of the connection frame 3 on the front side of the latter.

The upper side and underside of the subrack 9 are provided in each case with a clearance 13 over a large area and have no electrical shielding function. For shielding, a shielding plate 7 is screwed onto the webs 2 of the upper side of the upper subrack 9 and a further shielding plate 7 is screwed onto the webs 2 of the underside of the lower subrack 9. The perforation 6 running along the edges of the shielding plates 7 is in this case congruent with the perforation 6 of the webs 2.

The front edges of the shielding plates 7 likewise bear contact springs 18, which establish a connection with the respective subrack 9 and with the front covering.

The perforation 8 of the shielding plates 7, that is the openness, the diameter of the holes and the extent of the perforated area, and also the material can vary and can be adapted to correspond to the EMC and cooling requirements.

Consequently, an assembled composite subrack 14 does not have any intermediate bottoms which hinder free convection of the air from the bottom to the top. This design according to the invention acts in a way similar to a chimney and therefore offers a distinctly increased cooling capacity in comparison with the previous standard.

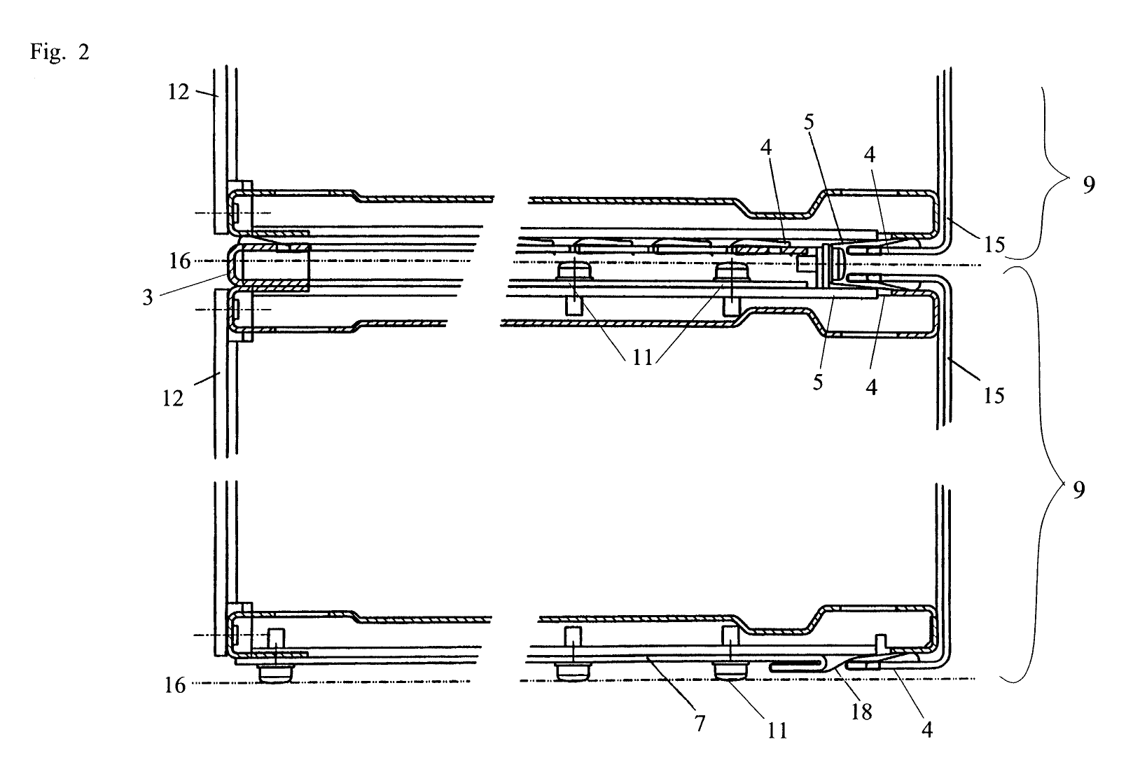

FIG. 2 shows a section along a side wall of the composite subrack according to the invention, the lower part being represented. The limit of the division between two subracks 9 is shown by a dash-dotted line 16.

The fastening of the individual parts of the composite subrack and the electrical bonding to one another can be seen well here.

The connection frame 3 is fastened to the lower subrack 9 by screws 11. The contact springs 4 on the upper side of the connection frame 3 bond the upper subrack 9. The bonding of the front covering 15 produces the contact spring 5 bent in a U-shaped form, located on the right-hand side of the connection frame 3 in FIG. 2. This contact spring 5 rests on both subrack surfaces and, when the front coverings 15 are closed, is additionally pressed into place and bonded by the contact springs 4 of the latter.

FIG. 2 also shows the fastening of the shielding plate 7 with the aid of screws 11 to the subrack 9. The bonding of the shielding plate 7 to the subrack 9 and to the front covering 15 takes place via the contact springs 18 of the shielding plate 7 and also the contact springs 4 of the front covering 15.

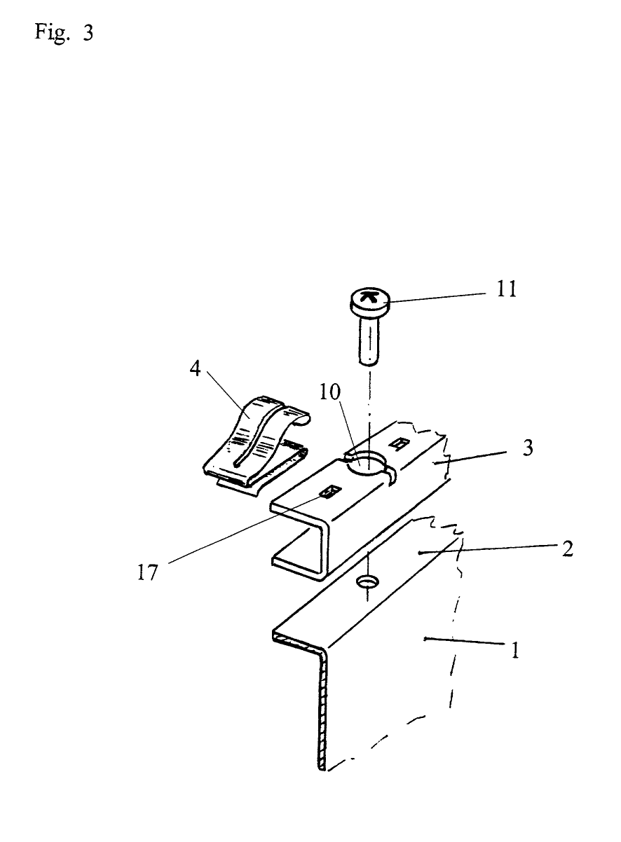

FIG. 3 shows in detail a number of selected components of the composite subrack according to the invention. The contact spring 4 is in a relaxed state here. It is fitted, for example inserted, into the depression 17 on the upper side of the connection frame 3.

The connection frame 3 is a C profile, the upper side of this C profile facing toward the inner side of the frame (here to the left). The perforation 10 of the connection frame 3 is designed in such a way that a screw 11 can be lowered into it, that is to say the bore on the upper side of the connection frame 3 allows the screw head to pass through. With the bore on the underside (covered here by the C profile), the connection frame 3 is securely screwed on the web 2, which is at right angles to the side wall 1 of the subrack.

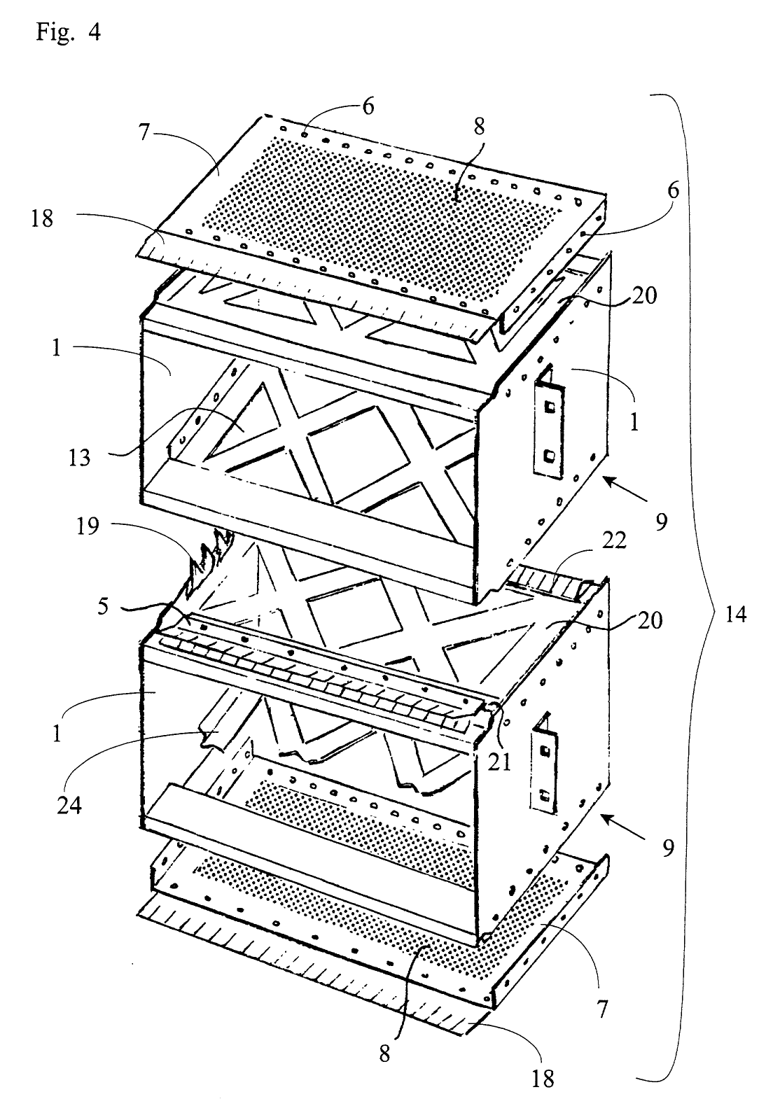

FIG. 4 shows a preferred exemplary embodiment of the composite subrack 14 according to the invention, which comprises two subracks 9 and also two shielding plates 7.

In comparison with FIG. 1, the functions of the intermediate frame have been integrated into the subracks 9 by developments explained below.

The two vertical side walls 1 of each subrack 9 are perforated at regular intervals at the upper edge and at the lower edge of the side wall 1.

The upwardly and downwardly terminating shielding plates 7 have, by analogy with FIG. 1, a large-area perforation 8, and also contact springs 18 at their front edges. Toward the side walls 1, the shielding plate 7 is bent downward by 90 degrees. These webs have a perforation 6 at short intervals, to permit screwing to the side walls 1. In addition, a perforation 6 is also provided toward the rear wall and at the contact springs 18.

The upper side 20 and the underside 24 of the subracks 9 are provided with a plurality of large-area clearances 13. Only half of the underside 24 of the lower subrack 9 is represented to afford a view of the lower shielding plate 7.

For the bonding of the two subracks 9 to each other, the lower subrack 9 bears springs 19 on its upper side 20. These springs 19 have been applied to the edges of the plates of the two side walls 1 of the subrack 9 and bring about an electrical connection of the side walls 1 to each other. For the sake of simplicity, only the springs 19 of the left-hand side wall 1 are shown here. Furthermore, this subrack 9 bears along its upper front side contact springs 5, which are fastened on a strut 21. The strut 21 is in turn fastened to the left-hand and right-hand side walls 1 of the subrack 9. Provided toward the rear wall is a row of triangular springs 22, which bond the subracks 9 to one another.

If the composite subrack 14 also comprises further subracks 9, all of them apart from the uppermost subrack 9 contain the springs 19, the triangular springs 22, and the contact springs 5.

This embodiment of the composite subrack 14 according to the invention represents a considerable simplification and improvement in comparison with the exemplary embodiment of FIG. 1, since here one component less is required (no intermediate frame). Consequently, only a single basic body for the subrack 9 and one basic body for the shielding plate 7 have to be manufactured in the production process. For the electrical bonding, inexpensive purchased parts, the bonding elements 5, 19 and 22, can be fitted or screwed on.

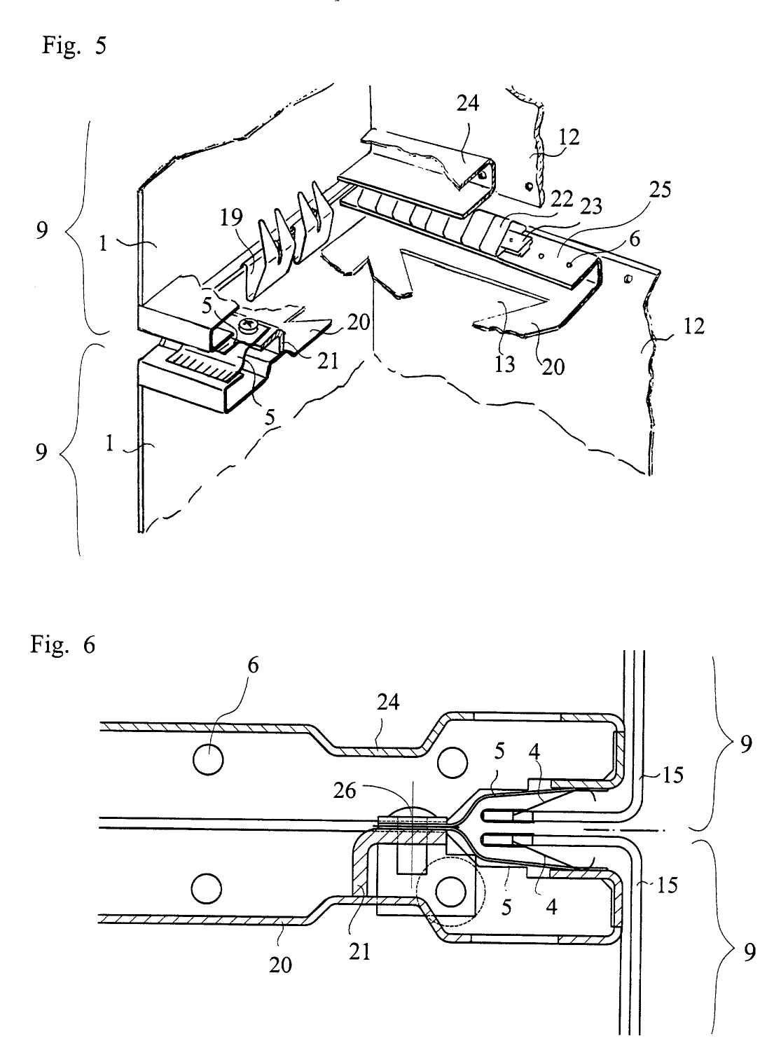

FIG. 5 shows a detail from the composite subrack with relevant electrical contact points for the bonding of the two subracks 9 according to the invention.

On the front side, two jointly mounted, comb-shaped contact springs 5 bond the two subracks 9 to each other, the upper contact spring 5 bonding the underside 24 of the upper subrack 9, the lower contact spring 5 bonding the upper side 20 of the lower subrack 9. The contact springs 5 are mounted by a screw on a strut 21, which runs between the two side parts 1 on the upper side 20 of the subrack 9.

Electrical connection of the side parts 1 of two neighboring subracks 9 to each other takes place via springs 19, which have been snap-fitted onto the edges of the plates of the side parts 1 of the lower subrack 9. The finger-shaped tongues of the springs 19 press against the side part 1 of the placed-on upper subrack 9.

Toward the rear wall 12, that is on the backplane side, the subracks 9 are bonded to each other via triangular springs 22. These triangular springs 22 are held by a rail 23 in such a way that they can be resiliently deflected well when they are pressed down with their gable-shaped tip by the bottom plate 20 of the upper subrack.

FIG. 5 also shows part of the upper side 20 of the subrack 9 with a clearance 13 over a large area. In this case, the upper side 20 is bent upward in a U-shaped manner on the rear wall side, so that a web 25 is formed. This web 25 is provided at short intervals with a perforation 6, so that the rail 23 can be screwed onto the web 25.

FIG. 6 shows a section along a side wall of the composite subrack. Here, the bonding of the front covering 15 to the individual subracks 9 is shown in more detail. The contact forces are intensified when the front coverings 15 are closed, that is, in the operating state via the contact springs 4 of the front covering 15, as already described in more detail in FIG. 2. The closed front covering 15 is at the same time connected with electrical continuity to the front edge of the subrack 9 via its contact springs 4.

The two contact springs 5 are fastened on a strut 21 by a screw 26. This strut 21 is in turn fastened to the left-hand and right-hand side walls 1 of the subrack 9. For better stability, the strut 21 is designed as an angled profile and is supported on the upper side 20 of the subrack. The strut 21 can consequently be prevented from twisting or sagging without a very thick material being required.

The circles 6 show the perforation on the side walls of the subracks 9.

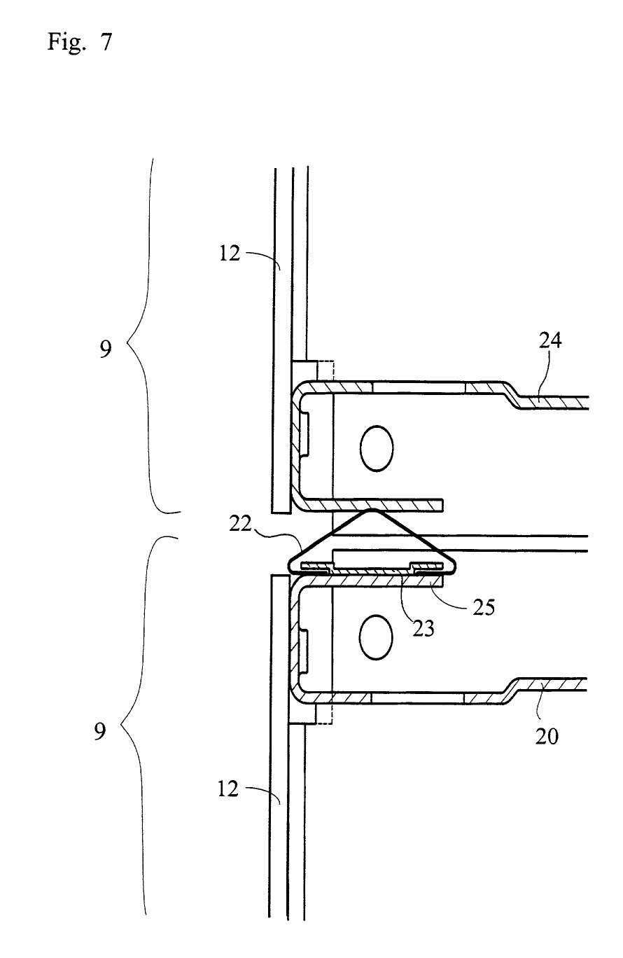

FIG. 7 shows once again a section through the side wall 1 of the composite subrack according to the invention, part of the rear wall 12, of the underside 24 of the upper subrack 9, of the upper side 20 of the lower subrack 9 and the triangular spring 22 being represented. Toward the rear wall 12, the subracks 9 are bonded to each other by these triangular springs 22, the gable-shaped tip of the spring 22 touching the underside 24. The spring 22 is held by a rail 23, which is fastened on the web 25, in such a way that it can be resiliently deflected well when it is pressed down by the underside 24 of the upper subrack 9. Here, too, the C profile of the underside 24 and of the upper side 20 of the subracks 9 can be seen.

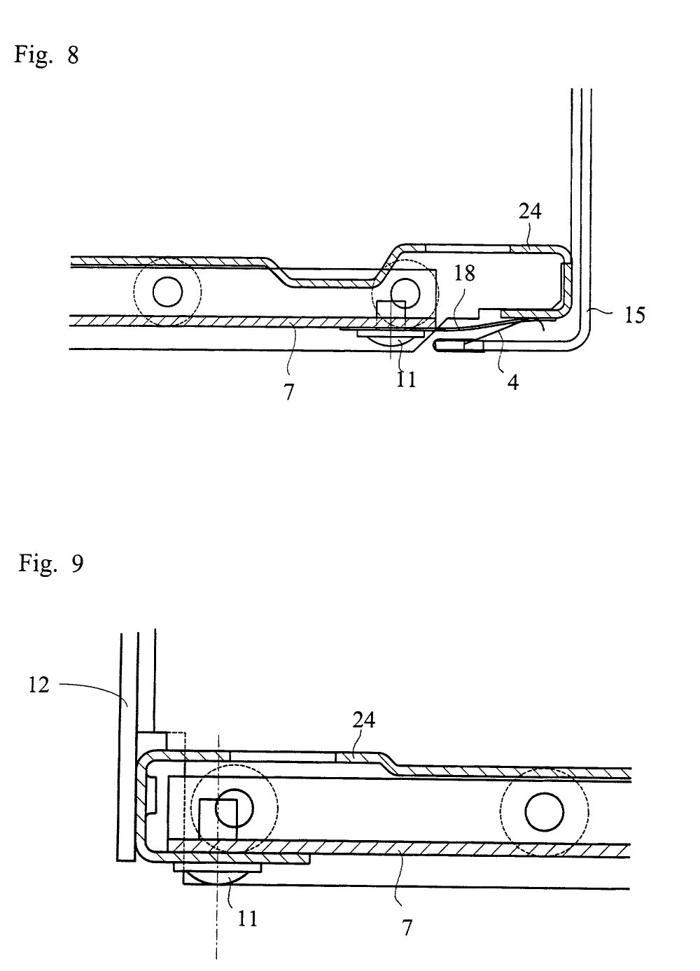

FIG. 8 shows, once again, a section through a side wall of the subrack 9, the bonding of the front covering 15 to the underside 24 of the lowermost subrack 9 and also to the shielding plate 7 of a composite subrack being represented.

On the front side, facing to the right in FIG. 8, a comb-shaped contact spring 18 is fastened to the edge of the shielding plate 7 with good electrical contact by a screw 11. The contact spring 18 rests on the shielding plate 7 over the full length, as can be seen from FIG. 4. Here, too, when the front covering 15 is closed, the bonding of the contact springs 4 to the underside 24 of the subrack 9 is intensified by the contact springs 18.

FIG. 9 shows the screwed connection of the downwardly terminating shielding plate 7 to the side wall (here section through a side wall) and also, toward the rear wall 12, to the underside 24 of the subrack 9 by screws 11 at short intervals (approximately 20 to 30 mm). The short interval is not a result of mechanical reasons, but should be kept as small as possible for good RF shielding.

It should be emphasized that the arrangement of the electrical connections from subrack to subrack allows small displacements with respect to one another, as caused, for example, by earthquakes, without contact being interrupted.

The features of the invention mentioned above can be used not only in the combination respectively specified, but also in other combination or on their own without departing from the scope of the invention.

Altogether, the invention provides a subrack and a composite subrack which bring about an improved cooling capability for modules which are arranged in the subrack.

The above-described apparatus is illustrative of the principles of the present invention. Numerous modifications and adaptations will be readily apparent to those skilled in this art without departing from the spirit and scope of the present invention.

What is claimed is:

1. A subrack for a composite subrack comprising:
two side walls;
an upper side;
an underside;
a front side; and
a rear wall, for receiving modules, wherein both the upper side and the underside of the subrack are respectively provided with at least one clearance over a large area.

2. The subrack as claimed in claim 1, wherein the surface area of the at least one clearance accounts for between 50% and 90% of the entire surface area of the upper side or the underside of the subrack.

3. The subrack as claimed in claim 1, further comprising:
webs on the upper side and on the underside of the subrack.

4. The subrack as claimed in claim 3, wherein the webs have, at least partly, a perforation.

5. The subrack as claimed in claim 1, wherein edge sidewall electrical bonding elements are provided on an edge of each side wall of the subrack situated toward the upper side.

6. The subrack as claimed in claim 1, wherein upper side front electrical bonding elements are provided on the upper side, situated toward the front side of the subrack.

7. The subrack as claimed in claim 1, wherein further upper side rear electrical bonding elements are provided on the upper side, situated toward the rear wall of the subrack.

8. The subrack as claimed in claim 1, further comprising a front covering with front covering electrical bonding elements which bond the subrack.

9. The subrack as claimed in claim 1, further comprising electrical bonding elements selected from the group consisting of:
a) edge sidewall electrical bonding elements provided on an edge of each side wall of the subrack situated toward the upper side;
b) upper side front electrical bonding elements provided on the upper side, situated toward the front side of the subrack;
c) further upper side rear electrical bonding elements provided on the upper side, situated toward the rear wall of the subrack; and
d) front covering electrical bonding elements on a front covering of the subrack which bond the subrack;
wherein the electrical bonding elements are, at least partly, of a flexible and electrically conducting design.

10. The subrack as claimed in the preceding claim 9, wherein the electrical bonding elements take a form of a contact spring.

11. The subrack as claimed in claim 1, further comprising at least one shielding plate, which shields the at least one large-area clearance of at least one of the upper side and the underside of the subrack.

12. The subrack as claimed in the preceding claim 11, wherein the shielding plate has, at least partly, a perforation.

13. The subrack as claimed in claim 11, wherein the shielding plate has a multiplicity of regularly distributed holes, the entire open surface area of the holes lying between 50% and 80% of the entire surface area of the shielding plate.

14. The subrack as claimed in claim 11, wherein the shielding plate has, at least at an edge facing toward the front side of the subrack, at least one bonding element for bonding the shielding plate, at least to the subrack.

15. A composite subrack comprising:
at least two subracks arranged one vertically above the other, the subracks comprising:
two side walls;
an upper side;
an underside;
a front side; and
a rear wall, for receiving modules, wherein both the upper side and the underside of each subrack are respectively provided with at least one clearance over a large area; and
two shielding plates each shielding at least one large-area clearance, shielding at least one large-area clearance of the upper side of the upper subrack and shielding at least one large-area clearance of the underside of the lower subrack.

16. The composite subrack as claimed in claim 15, further comprising a connection frame between two subracks.

17. The composite subrack as claimed in claim 16, wherein the connection frame has, at least partly, a perforation for fastening to a subrack.

18. The composite subrack as claimed in claim 16, wherein the connection frame has a multiplicity of bonding elements, which are arranged on the upper side or on the underside of the connection frame.

19. The composite subrack as claimed in claim 18, wherein the bonding elements comprise at least one of: a) upper side front electrical bonding elements provided on the upper side, situated toward the front side of the subrack, and b) upper side rear electrical bonding elements provided on the upper side, situated toward the rear wall of the subrack.

20. The composite subrack as claimed in claim 16, wherein the connection frame comprises:
at least one front edge bonding element at an edge lying toward the front side of the subrack, the front edge bonding element bonding at least the underside of the upper subrack and the upper side of the lower subrack.

21. The composite subrack as claimed in claim 16, wherein the connection frame comprises, at least partly, a C-profile, the opening of the C-profile facing inward.

22. The composite subrack as claimed claim 21, further comprising a fastener that can be lowered into the C-profile.

23. The subrack as claimed in claim 2, wherein the surface area of the at least one clearance accounts for between 70% and 90% of the entire surface area of the upper side or the underside of the subrack.

24. The subrack as claimed in claim 13, wherein the shielding plate has a multiplicity of regularly distributed holes, the entire open surface area of the holes lying between 65% and 75%, of the entire surface area of the shielding plate.
